(19) United States
(12) Patent Application Publication
(10) Pub. No.: US 2025/0335668 A1
(43) Pub. Date: Oct. 30, 2025

(54) COMPUTER-IMPLEMENTED METHOD FOR TESTING AND/OR DEVELOPING CONTROL SOFTWARE, AND CORRESPONDING COMPUTING ENVIRONMENT FOR DATA PROCESSING

(71) Applicant: dSPACE GmbH, Paderborn (DE)

(72) Inventors: Nicola BRUSKI, Paderborn (DE); Marco SCHMIDT, Paderborn (DE)

(73) Assignee: dSPACE GmbH, Paderborn (DE)

(21) Appl. No.: 19/188,610

(22) Filed: Apr. 24, 2025

(30) Foreign Application Priority Data
Apr. 24, 2024 (DE) 10 2024 111 447.9

(51) Int. Cl. G06F 30/27

(52) U.S. Cl. CPC G06F 30/27

(57) ABSTRACT

A computer-implemented method for testing and/or developing control software, having a computing environment, and a simulation model calculated in the computing environment. The simulation model interacts with the control software by outputting input values to the control software and by receiving output values from the control software. The control software includes an AI component, which can be executed synchronously with the simulation model by the computing environment. In addition, the invention relates to a computing environment for data processing comprising a computer system for carrying out the above method, a computer program product, and a corresponding computer-readable data carrier.

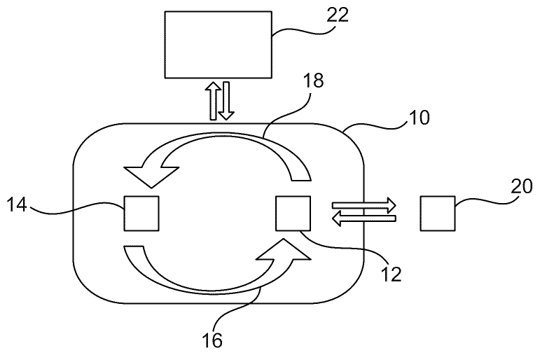

This nonprovisional application claims priority under 35 U.S.C. § 119(a) to German Patent Application No. 10 2024 111 447.9, which was filed in Germany on Apr. 24, 2024, and which is herein incorporated by reference.

### BACKGROUND OF THE INVENTION

### Field of the Invention

The invention relates to a computer-implemented method for testing and/or developing control software. In addition, the invention relates to a computing environment for data processing for carrying out the method. Also, the invention relates to a computer program product comprising instructions that, when the program is executed by a computer, cause the latter to carry out the above method. Furthermore, the invention relates to a computer-readable data carrier on which the above computer program product is stored.

### Description of the Background Art

Solutions based on artificial intelligence (AI) are increasingly taking on control functions in the automotive field. In addition to tasks associated with autonomous driving and/or assistance systems, this also includes functions that until now have been taken on by classic, non-AI-based control software.

Control software with an AI component, as well as AI components for control software, should, just like classic, non-AI-based control software, be verified or validated with the aid of various review methods before they are used.

For functional tests of software of electronic control units (ECUs), for example, hardware in the form of the control unit or in the form of a control unit prototype can be used, in principle, and the control software can be tested in actual road testing. In addition to the high costs and the very high expenditure of time, the lack of reproducibility on account of the complex environmental conditions is problematic with such tests, however.

Furthermore, so-called hardware-in-the-loop (HIL) tests are a possibility, in which the ECU is connected to an HIL simulator through inputs and outputs, wherein the HIL simulator models the real environment. The HIL simulator emulates the electrical signals from sensors and actuators that are read by the ECU. For example, in an HIL test of an internal combustion engine, the signals from crankshaft and camshaft sensors are created by an angular processing unit (APU) that is part of the hardware of the HIL simulator. On the basis of these signals, the ECU, in turn, generates sensor and/or actuator control signals by means of the control software that in turn bring about a change in the electrical signals in the HIL simulator. The route, which in real road testing would be traveled as a test track and thus generate different electrical signals for the control unit, is represented within the HIL simulation as a route model. In order to perform an HIL test, however, the development of an ECU must already be relatively far advanced since the ECU is connected as hardware to the HIL simulator.

Hardware-independent software tests are necessary in order to permit earlier tests of the control software, for example at a point in the development process when no hardware is yet available. Software-in-the-loop (SIL) tests can be used for this purpose, for example. In SIL tests, the environment of the software to be tested—also referred to as software under test (SUT)—must, on the one hand, be simulated by a simulation model. Furthermore, the test cases are also simulated by the simulation model in SIL tests. During the SIL test, the SUT interacts with the simulation model in order to thus obtain information about the control software. This information can also be used to (further) develop the control software, so SIL tests in an early phase are also useful for software development.

Since AI components for control software (thus far) constitute only a small part of the control software, and upstream and/or downstream functions are taken on by non-AI-based algorithms, the AI component is statically integrated into the simulation model in the case of hardware-independent software tests. Because the AI component is thus effectively a part of the simulation model, this has the disadvantage in the case of tests in which the SUT interacts with the simulation model that the entire simulation model must be translated anew into executable machine code when there is a change to the AI component for the test. This makes the test process complex and expensive. Furthermore, it is disadvantageous that the AI component cannot be changed during the test process without stopping the test. Consequently, there is a need to simplify the use of AI components for control software as well as the testing thereof.

### SUMMARY OF THE INVENTION

It is therefore an object of the invention to provide a method for testing and/or developing control software in which the AI component can be changed simply. An additional object of the invention is to provide a method for testing and/or developing control software that permits rapid development times.

According to an example of the invention, a computer-implemented method for testing and/or developing control software is provided, having a computing environment, and having a simulation model calculated in the computing environment, wherein the simulation model interacts with the control software by outputting input values to the control software and by receiving output values from the control software, wherein the control software includes an AI component, and wherein the AI component is executed synchronously with the simulation model by the computing environment.

An aspect of the invention is that the AI component is not part of the simulation model, but rather a component of the control software, and in the SIL test is thus a part of the software under test (SUT). In addition to the AI component—for example, an AI-based driving function—the control software can also have additional non-AI-based components here, for example software components for data acquisition and/or data preparation. Alternatively, the control software can include solely the AI component(s). By means of the method, it is possible to test the AI component during the interaction with the simulation environment. An advantage of this is that a change in the AI component can be accomplished independently of the simulation model. Accordingly, the AI component can be modified without a new translation of the simulation model into executable machine code. Since, moreover, the AI component is executed synchronously with the simulation model by the computing environment, a real-time capability, and thus reproducibility, of the test is ensured.

For the purposes of the invention, real-time capability may mean that processes that are intended and specified for execution by a specific point in time are indeed executed and completed by this point in time. In the context of hardware-independent software tests, the question of real-time capability is not tied to an absolute measure of speed, since time in the simulation can be compressed or stretched as needed. However, it is necessary for the reproducibility of the tests that the actions planned within a time interval are indeed executed within the specified time interval, so that the sequence of the actions executed between the different time intervals is defined.

Since the AI component is not part of the simulation model, but instead runs independently of the simulation model, a further advantage is that it is not necessary to interrupt the test process in order to change the AI components. Accordingly, the method permits especially user-friendly testing and/or development of the control software. The method thus makes it possible that the AI components can be loaded on the real-time side of the test, and parameters of the AI components can be manipulated, at the runtime of the simulation model.

The simulation model calculated in the computing environment interacts with the control software by outputting input values to the control software and by receiving output values from the control software. The simulation model calculates the environment of the control software in this case. For example, in the case of a motor control unit, the physical processes in an (electric) motor and the resultant sensor data represent the environment of the motor control unit. In the case of an autonomous driving function, in contrast, the surroundings of the vehicle and the resultant data streams from the simulated environmental sensors represent the environment of the driving function. Moreover, the simulation model also calculates the output values for the test cases. A test case for a motor control unit can be, for example, a failure of the cooling, and for a driving function another vehicle cutting in. Test cases each include a pair composed of input values and the output values expected for them. The calculation of the output values is taken on by the simulation model.

A more realistic test scenario is therefore provided by the method according to the invention than in the case of a purely virtual test of the AI component with training data and/or test data, since the behavior of the AI component can, if applicable, be tested in a reproducible manner with other components of the control software, in combination with the environment simulated by the simulation model, and, if there is sufficient computing capacity, with the entire simulated vehicle.

The AI component can be an AI component trained on learning data. Preferably, the AI component was trained offline and is used as a trained AI component in the control software. For example, the AI component can have been trained with the aid of the Python programming language and appropriate learning data. In other words, therefore, the present method is not a method for training the AI component. Instead, it is a method for testing the behavior of the control software containing the AI component.

The AI component can be made available via a program library of the control software compiled for the computing environment. Especially preferably, the trained AI component is provided via a Python library. Further preferably, provision is made that, in other words, the computing environment accesses program libraries of Python implementations that have been compiled for the computing environment in which the simulation model is executed. This can be the “TensorFlow Lite” library, the “Scikit learn” library, or “PyTorch,” for example.

The computing environment can support the programming language in which the AI component made available by the program library is written. Accordingly, the AI component can be executed by the computing environment. In this case, provision is further preferably made that the computing environment ensures the synchronous execution of the AI component with simulation steps of the simulation model, as well as the timely execution of individual statements of the AI component—which is to say the real-time capability.

The executing of the AI component can include an importing of modules, preferably from the program library, during an initialization phase of the AI component by the computing environment. In other words, therefore, preferably the modules are imported during the initialization phase of the AI component. Further preferably, provision is made that the importing can be divided into multiple time slices in such a manner that the real-time capability is ensured. “Divided into multiple time slices” is understood in the present case to mean, in particular, that the entire module is not imported at once, regardless of how long the importing takes. Instead, the module or parts of the module are each preferably imported within a predefined time interval—which is to say the time slice.

The executing of the AI component can include an executing of precompiled byte code of the AI component by the computing environment and, in particular, by a virtual machine of the computing environment. In other words, provision is preferably made that the computing environment includes a virtual machine matched to the requirements, especially preferably a process-based virtual machine. The virtual machine, for example a “Python virtual machine,” thus preferably executes the precompiled byte code from the imported module. Stated differently, the AI components is executed [sic; should say “AI component”] in a runtime environment provided by the computing environment by means of the virtual machine.

Byte code can be understood in the present case to be a collection of instructions in binary form for the virtual machine. Unlike source texts or scripts, byte code is not “human-readable.” Instead, program statements are coded as “bytes” as for machine code. In contrast to machine code, which is executed directly by a processor, the byte code must be “interpreted,” however. In this context, provision is made according to another preferred improvement of the invention that the precompiled byte code is translated into machine code by means of a just-in-time compiler for execution. The byte code thus is not compiled in its entirety before its execution, but only during the runtime. The just-in-time compilation of the AI component has the advantage that information about the (partially) executed AI components can be gathered and used at runtime.

The executing of the AI component can include an executing, divided into time slices, during the runtime of the simulation model by the computing environment, of modules preferably imported from the program library. In this way, the synchronous and real-time-capable execution of the AI component with the simulation model can be ensured in an especially simple manner.

An executing, divided into time slices, of the imported modules during the runtime of the simulation model can include that a time interval such as, e.g., 50 μs, is defined initially. After that, preferably the executing of a function of the imported module is initiated, wherein the function of the module generally uses a multiple of the defined time interval for complete execution. When the function exceeds the duration of the time interval, the state of the function preferably is frozen.

The function can be, for example, an inference of the AI component. The inference is the process in which a trained machine learning model draws conclusions from data that do not correspond to the learning data.

Subsequently, the simulation step forming the basis of this time interval can be terminated, which preferably means that the entire simulation step of the simulation model is also terminated. It is ensured in this way that the duration of the simulation step—for example 1 ms—is not exceeded.

In the next simulation step, the computing environment can restore the frozen state of the function and continues at exactly the point at which the function was previously interrupted in order to repeat the above-described process for the next time interval.

With regard to the simulation model, the simulation model can include an environment model and a test model for influencing the environment model. Preferably, the environment of the control software is calculated by means of the environment model, whereas the test cases are calculated by means of the test model. Preferably, provision is made in this case that the test model changes variables of the environment model in a targeted manner in order to create the test cases. This has the advantage that the environment model need neither be halted nor changed in order to perform the test, and the real-time capability can be ensured.

Additional technical features and advantages are evident to the person skilled in the art from the following description of the computing environment for data processing, a computer program product, and/or a computer-readable data carrier, as well as from the example.

The object of the invention is also attained by the computing environment for data processing comprising a computer system for carrying out the method described above. According to an example, the computing environment for data processing is a computing environment designed as a server. This makes it possible that the user themselves need not maintain any hardware resources for carrying out the method for testing and/or developing the control software, but that the method is instead made available to the user on a server. Therefore, the method in this case is a server-side application. In an example, the computing environment is a computer. Preferably, the computer can be operated in a distributed manner, so the method in this case is a client-side application. Whether server-based or not, provision is further preferably made that the computing environment is equipped with a virtual machine for providing a runtime environment.

In addition, the invention relates to a computer program product comprising instructions that, when the program is executed by a computer, cause the latter to carry out the above method.

Furthermore, the invention relates to a computer-readable data carrier on which the above computer program product is stored. Preferably, the instructions are embedded on the computer-readable data carrier, and, when they are executed by a processor of the computer or of the server, the instructions cause the processor to carry out the method for testing and/or developing the control software.

The technical advantages and effects of the computing environment for data processing, the computer program product, and the computer-readable data carrier are evident to the person skilled in the art from the description of the method for testing and/or developing the control software, as well as from the example described below.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWING

The present invention will become more fully understood from the detailed description given hereinbelow and the accompanying drawing which is given by way of illustration only, and thus, are not limitive of the present invention, and wherein the sole FIGURE schematically shows a computing environment, in which a method for testing and/or developing control software according to an example of the invention is carried out.

### DETAILED DESCRIPTION

The FIGURE schematically shows a computing environment 10 in which a method for testing and/or developing control software 12 according to an example is carried out. In the example, the control software 12 is a circuit of a transmission of an electric-powered vehicle. The control software 12 has at least one AI component, and the transmission is controlled with a neural network in the present case. The control of the transmission is especially important for (partially) autonomous vehicles, which are to select the correct gear as a function of the driving situation or the parking situation. Since what is involved is the control of a transmission of an electric-powered vehicle, only the modes park, drive, neutral, and reverse are present.

As can be seen in the FIGURE, a simulation model 14 is calculated in the computing environment 10. During the test, the simulation model 14 interacts with the control software 12 by outputting input values (illustrated by arrow 16) to the control software 12 and by receiving output values (illustrated by arrow 18) from the control software 12.

The simulation model 14 includes an environment model, which calculates the environment of the control software 12, and a test model for influencing the environment model. In the example, the environment model calculates the gearshift lever, the accelerator pedal, the speedometer, the switch for automatic parking, as well as speakers of the vehicle. The test cases are calculated by means of the test model, wherein for this purpose the test model changes the variables of the environment model in order to create the test cases. The following test case is calculated in the example:

The test case begins with straight-ahead driving, then the switch for automatic parking is actuated at full speed. The AI component—which is to say the neural network—of the control software 12 is to decide during the test when shifting and driving are to take place. The response of the AI components is checked for correctness by components of the computing environment 10.

By means of the computing environment 10, the AI component of the control software 12 is executed synchronously with the simulation model 14, so the test is reproducible. In addition, it can be seen in the FIGURE that the AI component is made available via a program library 20 of the control software 12 compiled for the computing environment 10. It can furthermore be seen in the FIGURE that the computing environment 10 is designed in the present case as a server, or the method for testing and/or developing the control software 12 is operated on the server side. In order to perform the test, a user connects to the computing environment 10 by, for example, a computer 22, a handheld mobile device, etc. In addition, provision is made in this example that software for, e.g., graphical creation and/or management of simulation models 14 and/or control software 12 is maintained on the computer 22. Consequently, the user has the capability to load the simulation model 14 that is suitable for his purposes as well as the control software 12 to be tested from the computer 22 into the computing environment 10 in order to carry out the method for testing and/or developing the control software 12 in the computing environment.

In principle the AI-component in the sense of this application could be or could be at least part of the software of any control system of the vehicle. Examples of such AI-component control systems are, for example, automated emergency braking system, driver assistant systems, perception algorithms, automatic vehicle speed control systems, adaptive cruise control systems, parking assistance systems, etc. The AI-component(s) can also be used to control less complex systems in a vehicle, for example, engine control systems, anti-lock braking systems, anti-theft systems, etc.

In a practical application a user would train an ai-component based on the requirements of its intended application in a control system. For this task he could use publicly available machine learning libraries such as PYTORCH, JAX or TENSORFLOW. While the training of AI components is computationally intensive, significantly less computing power is required to execute the AI-components. This enables the use of these components with computational hardware typically found in an automotive vehicle. When the control software including the AI-component is compiled to machine code for the use with a specific hardware a substantial amount of time is needed for the compiling and if the specific hardware is not known then it may not be possible to properly compile the combined control software and AI-component(s). Thus, it is advantageous, in an example of the invention, to use bytecode in combination with a just in time compiler and/or a hardware specific runtime environment, which can be, for example, LiteRT. This enables the flexible exchange of the hardware as well as the AI-component. This is especially useful during the development of such a component when the hardware is not yet specified, and the component goes through multiple iterations. Thus, the complete control software does not need to be re-compiled for any changes, such as adding, deleting, or modifying AI-components. Another aspect in the development of complex control-software is that an individual developer who is responsible for the improvement of a single component might not have access to all other components which are necessary for a complete compilation due to legal or organizational restrictions. The use of precompiled bytecode of the remaining components thus also solves this issue.

Therefore, an important aspect of the development of the control system is the testing and validation of these systems. A user who is developing such a system would therefore frequently evaluate its performance in specific tests. These tests are typically caried out as software in the loop test and/or hardware in the loop tests, whereby the control software interacts with a computer-simulation of the relevant parts of the physical system it is intended to control. In case of an emergency braking systems this, for example, is a simulation of the outputs of the sensor systems of an automotive vehicle that will be equipped with such. In case of a driver assistant system this might be a dynamic simulation of the chassis of the automotive vehicle as well as the resulting sensor signals from various sensors. To execute a test which gives an indication of the reaction of the control system to a change of the state of the simulated environment a third software component of the test model is necessary. This model deliberately influences the state of the simulated environment to investigate the reaction of the control system.

As these software components are interacting with each other in these tests it is an essential requirement that they are executed in time. While it is possible to fulfill this requirement by using a single software process to execute the components it is advantageous to use two separate processes. While one process executes the simulation of the environment the other process execute the test model and the control system. In this process the test model encompasses the control system thus enabling the described manipulation of its environment.

This approach enables a flexible exchange, the independent development of the software components. It especially enables the use of the same environment simulation with multiple different software controls. A method which enables the execution in time is described in U.S. Pat. No. 7,933,734, which is incorporated herein by reference. This configuration is called a real time testing system. The software executing the environment simulation as well as the test model are specifically designed to guarantee the execution in time. The later includes the use of bytecode which has been specifically generated according to this purpose.

Herein the execution in time has two aspects. The first is the execution within a predictable physical time window. The second aspect, which is implicitly included in the first, is the execution in a predictable order. While for HIL-Testing both aspects are relevant, for SIL-Testing only the later is necessary. Thus, enabling the speed up of the execution of those tests.

To guarantee the timing requirements, the described real time testing system is executed within a closed system that does not allow direct exchange with the operating system of the host.

A user who wants to evaluate a control system which includes an AI-Component would want to include the AI-Component as well as the necessary runtime environment into the test model. As the generation of the bytecode of these software components has not been adapted to the timing requirements, this has not been possible yet, i.e. the AI-Component could not be evaluated.

To solve this issue the invention allows the execution of the runtime environment from the host system into the test model synchronously, thus enabling the execution of the AI component thereby abandoning the strict timing requirements. Nevertheless the interaction between the simulation of the environment and the control system as well as the manipulation of their interaction by the test model is enabled.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for testing and/or developing control software, the method comprising:
providing a computing environment and a simulation model that is calculated in the computing environment, the simulation model interacting with control software by outputting input values to the control software and by receiving output values from the control software; and
providing the control software with an AI component that is executed synchronously with and separately from the simulation model by the computing environment.

2. The method according to claim 1, wherein the AI component is an AI component trained on learning data.

3. The method according to claim 1, wherein the AI component is made available via a program library of the control software compiled for the computing environment.

4. The method according to claim 1, wherein the executing of the AI component includes an importing of modules or from a program library, during an initialization phase of the AI component by the computing environment.

5. The method according to claim 1, wherein the executing of the AI component includes an executing of precompiled byte code of the AI component by the computing environment and by a virtual machine of the computing environment.

6. The method according to claim 5, wherein the precompiled byte code is translated into machine code via a just-in-time compiler for execution.

7. The method according to claim 1, wherein the executing of the AI component includes an executing, divided into time slices, during a runtime of the simulation model by the computing environment of modules imported from the program library.

8. The method according to claim 1, wherein the simulation model includes an environment model and a test model for influencing the environment model.

9. A computing environment for data processing comprising a processor for carrying out the method according to claim 1.

10. A computer program product comprising instructions that, when the program is executed by a computer, cause the computer to carry out the method according to claim 1.

11. A computer-readable data carrier on which the computer program product according to claim 10 is stored.
